(19) United States
(12) Patent Application Publication
(10) Pub. No.: US 2016/0093660 A1
(43) Pub. Date: Mar. 31, 2016

(54) Semiconductor apparatus and method of manufacturing semiconductor apparatus

(71) Applicant: c/o SONY CORPORATION, Tokyo (JP)

(72) Inventor: Kunio Anzai, Kanagawa (JP)

(21) Appl. No.: 14/954,988

(22) Filed: Nov. 30, 2015

Related U.S. Application Data
(62) Division of application No. 13/200,645, filed on Sep. 28, 2011.

(30) Foreign Application Priority Data
Oct. 27, 2010 (JP) 2010-240386

(51) Int. Cl. H01L 27/146; H01L 29/423

(52) U.S. Cl. CPC H01L 27/14643; H01L 27/14614; H01L 27/1461; H01L 27/14607; H01L 29/42364

(57) ABSTRACT

A semiconductor apparatus includes: an MOS type field effect transistor formed on a semiconductor substrate and having a first gate electrode set at a predetermined impurity concentration; and a charge modulation device formed on the semiconductor substrate and having a second gate electrode set at a predetermined impurity concentration lower than the impurity concentration of the first gate electrode.

### FIELD

The present disclosure relates to semiconductor apparatus and, more particularly, to a method of manufacturing a semiconductor apparatus including CMDs (charge modulation devices) and MOSFETs formed on the same semiconductor substrate.

### BACKGROUND

Solid-state imaging apparatus employing CMDs (charge modulation devices) as pixels are known. In some device structures used for CMDs, for example, a source and a drain are formed such that a current will flow between the source and drain in parallel with a surface of a semiconductor layer. Some proposed apparatus have a configuration in which a gate electrode formed on a surface of a semiconductor layer between a source and a drain formed as thus described with an insulation film interposed between the semiconductor layer and the gate electrode (for example, see FIG. 2 in JP-A-2009-152234 (Patent Document 1)).

In the case of a solid-state imaging apparatus, it is advantageous in miniaturization of the apparatus if a pixel region having pixels arranged therein and a logic area having circuits for driving the pixels formed therein are formed on one semiconductor substrate.

### SUMMARY

A problem as described below can occur in a solid-state imaging apparatus which includes a pixel area having pixels constituted by CMOs arranged therein and a logic area formed on one semiconductor substrate.

MOSFETs (metal oxide semiconductor filed-effect transistors) are used as transistor devices provided in the logic area. The MOSFETs are preferably provided with as high on/off transition performance as possible. For this purpose, an on-current of such a MOSFET may be increased by, for example, increasing a channel-gate capacity between the channel and the gate of the MOSFET. The on-current may be increased forming a gate insulation film, which is a silicon oxide film, with a small thickness.

The CMOs of such an apparatus are preferably formed such that carriers (electrons or holes) generated as a result of photoelectric conversion will cause a change in a source voltage with the highest possible efficiency. For this purpose, a channel-gate capacity between a channel and a gate may be kept smaller than a sensor-channel capacity between a senor section and the channel. That is, what is required is to keep the sensor-channel capacity as large as possible and to keep the channel-gate capacity as small as possible. The channel-gate capacity can be kept small by forming a gate insulation film with a large thickness, which is the reverse of the step taken in a MOSFET.

As thus described, MOSFETs provided in a logic area and CMDs provided in a pixel area face a trade-off between the thickness of their respective gate insulation films and the required performance of the devices. Therefore, when a pixel area and a logic area are to be formed on the same semiconductor substrate, it is required to form gate insulation films in the pixel area and gate insulation films in the logic area at separate manufacturing steps. In this case, the number of steps for manufacturing an apparatus is increased for reasons such as a need, for forming patterning masks to be used for the logic area and the pixel area at different manufacturing step which results in an increase in the production cost and an increase in the turn around time (TAT).

Under the circumstance, it is desirable to satisfy both of the requirement of forming MOSFETs and CMDs on one semiconductor substrate and the requirement of providing the MOSFETs and the CMDs with high performance using efficient manufacturing steps.

An embodiment of the present disclosure is directed to a semiconductor apparatus including an MOS type field effect transistor formed on a semiconductor substrate and having a first gate electrode set at a predetermined impurity concentration and a charge modulation device formed on the semiconductor substrate and having a second gate electrode set at a predetermined impurity concentration lower than the impurity concentration of the first gate electrode. Thus, the resistance of the second gate electrode of the charge modulation device is set higher than the resistance of the first gate electrode of the MOS type field effect transistor.

In the semiconductor apparatus according to the embodiment of the present disclosure, the impurity concentration of the first gate electrode may be set such that the capacity of a first depletion layer generated at an interface between the first gate electrode and a first gate insulation film formed between the first gate electrode and the semiconductor substrate will not exceed a predetermined value, and the impurity concentration of the second gate electrode may be set such that the capacity of a second depletion layer generated at an interface between the second gate electrode and a second gate insulation film formed between the second gate electrode and the semiconductor substrate will exceed the capacity of the first depletion layer. Thus, a channel-gate capacity of the MOS type field effect transistor is set at a great value and a channel-gate capacity of the charge modulation device is set at a small value.

In the semiconductor apparatus according to the embodiment of the present disclosure, the semiconductor substrate may have a pixel area having pixels arranged therein and a circuit area including a driving circuit for driving the pixels. The charge modulation device may be formed as a pixel. The MOS type field effect transistor may be formed in the circuit area. Thus, the impurity concentrations of the first gate electrode and the second gate electrode are set at doping steps for setting different impurity concentrations in regions defined in association with the pixel area and the circuit area, respectively.

In the semiconductor apparatus according to the embodiment of the present disclosure, an impurity with which the first gate electrode is doped may be the same substance as an impurity with which the second gate electrode is doped. Thus, part of doping steps for setting the impurity concentrations is carried out as a common process.

In the semiconductor apparatus according to the embodiment of the present disclosure, the first gate electrode and the second gate electrode may be formed from the same electrode material layer. Thus, the first gate electrode and the second gate electrode are simultaneously formed by processing an electrode material layer at the same manufacturing step.

In the semiconductor apparatus according to the embodiment of the present disclosure, a first gate insulation film formed between the first gate electrode and the semiconductor substrate and a second gate insulation film formed between the second gate electrode and the semiconductor substrate may be formed from the same insulation film material layer. Thus, the first gate insulation film and the second gate insulation film are simultaneously formed by processing an insulation film material layer at the same manufacturing step.

Another embodiment of the present disclosure is directed to a method of manufacturing a semiconductor apparatus, including: doping an electrode material layer formed from a material of a gate electrode with an impurity, the electrode material layer being formed on a semiconductor substrate having a first area including an MOS type field effect transistor and a second area including a charge modulation device, the doping employing a dose associated with a first impurity concentration at which a gate electrode of the charge modulation device is to be set; forming a mask using such a masking pattern that the second area is masked and the first area is not masked; and doping the electrode material layer with the impurity with the mask thus formed using a dose according to a difference between the first impurity concentration and a second impurity concentration at which the gate electrode of the MOS type field effect transistor is to be set. Thus, the gate electrode of the MOS type field effect transistor in the first area is set at the second impurity concentration, and the gate electrode of the charge modulation device in the second area is set at the first impurity concentration that is lower than the second impurity concentration.

According to the embodiments of the present disclosure, a MOSFET and a CMD having high performance can be formed on one semiconductor substrate using efficient manufacturing steps.

### BRIEF DESCRIPTION OF THE DRAWINGS

FIG. 1 is an illustration of an exemplary general structure of a solid-state imaging apparatus according to an embodiment of the present disclosure;

FIG. 2 is an equivalent circuit diagram of a CMD; FIG. 3 is an illustration of a sectional structure of the CMD;

FIG. 4 is an illustration of a sectional structure of a MOSFET;

FIG. 5 is a band diagram showing the state of an interface between a gate electrode and a channel of the CMD;

FIG. 6 is a band diagram showing the state of an interface between a gate electrode and a channel of the MOSFET;

FIGS. 7A and 7B are illustrations showing exemplary steps of manufacturing the solid-state imaging apparatus;

FIGS. 8A and 8B are illustrations showing exemplary steps of manufacturing the solid-state imaging apparatus; and

FIG. 9 is an illustrations showing a modification of the steps of manufacturing the solid-state imaging apparatus.

### DETAILED DESCRIPTION

Embodiments of the present disclosure will now be described in the following order.

1. First Embodiment (example in which CMDs and MOSFETs are different from each other in terms of the concentration of impurities used in their respective gate electrodes)

2. Modifications

### 1. First Embodiment

[Exemplary General Configuration of Solid-State Imaging Apparatus]

A solid-state imaging apparatus which is a semiconductor apparatus according to the present disclosure employs CMDs (charge modulation devices) to serve as pixels. Each CMD has a source region and a drain region formed such that a current will flow in parallel with a surface of a semiconductor layer. A gate is provided on a surface of the semiconductor layer between the source region and the drain region with an insulation layer interposed between the surface and the gate. Thus, there is provided an electrostatic induction transistor having a so-called horizontal structure in which a gate region, a drain region, and a source region are horizontally disposed.

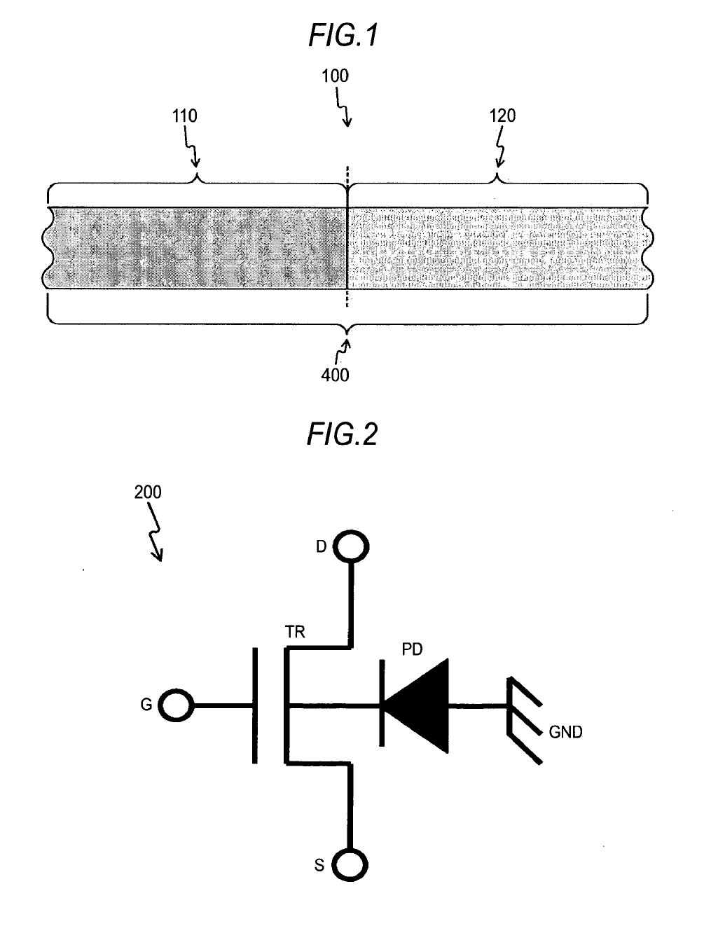

FIG. 1 a schematic sectional view of a solid-state imaging apparatus 100 according to the present embodiment of the present disclosure showing an exemplary general configuration of the apparatus. Referring to the physical structure of the solid-state imaging apparatus 100, the apparatus includes a pixel area 110 and a logic area 120 provided on one semiconductor substrate 400, as illustrated. In the pixel area 110, a multiplicity of pixels constituted by CMOs are provided in the form of a planar matrix-like array. The logic area 120 primarily includes circuits for driving the pixels in the pixel area 110. Transistors provided in such circuits in the logic area 120 are MOSFETs (metal oxide semiconductor field effect transistors). The pixel area 110 is an example of the second area referred to in the appended claim(s). The logic area 120 is an example of the circuit area and the first area referred to in the appended claim(s).

### [Equivalent Circuit of CMD]

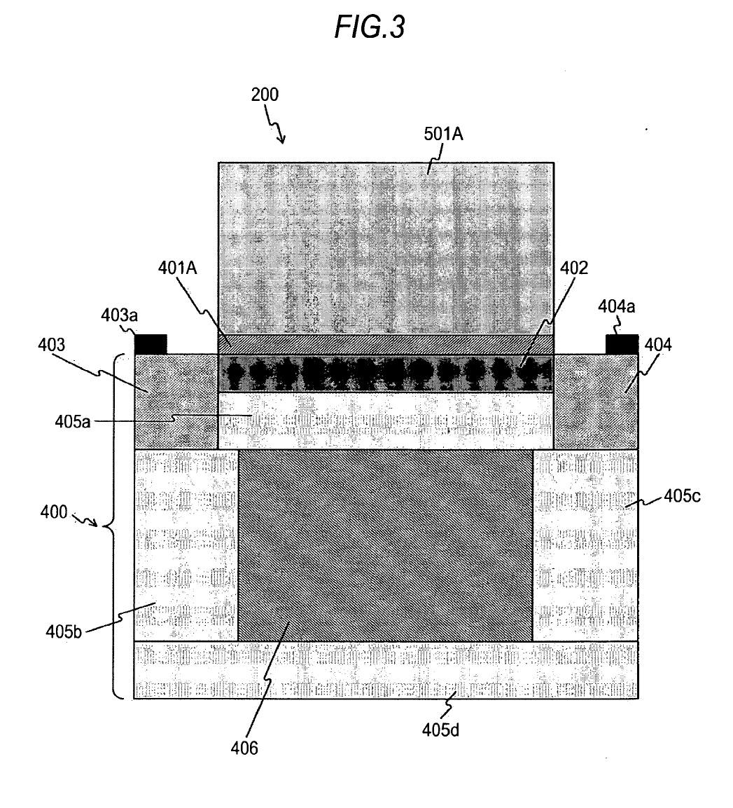

FIG. 2 shows an equivalent circuit of a CMD 200 provided as a pixel in the pixel area 110. As shown in FIG. 2, the CMD 200 is formed by connecting one photodiode PD to one transistor TR. The photodiode PD is a part which performs photoelectric conversion, and a current according to the quantity of received light flows through the photodiode. To enable the photoelectric conversion of the CMD, the photodiode PD is formed on a bottom side of the transistor TR. The anode of the photodiode is connected to the ground in the illustration. In practice, the anode is connected to a well region, which is equivalent to connecting the anode to the ground.

Although not shown, the transistor TR is connected to a column signal line associated therewith, and a load current source is also connected to the column signal line. The transistor TR forms a source follower in combination with the load current source, and electrical charge obtained by the photodiode PD is amplified and output to the column signal line associated therewith.

The circuit diagram in FIG. 2 indicates that a CMD 200 has a photoelectric conversion function and a signal amplifying function. A CMD 200 having a configuration as shown in FIG. 2 includes no floating diffusion. A floating diffusion is a part of a pixel circuit for transferring electrical charge accumulated in a photodiode PD of the circuit. In a CMD 200, electrical charge generated by receiving light at the photodiode PD is held or accumulated unless a reset takes place, and the electrical charge is not extinguished even when it is read out as a signal. Thus, what is called non-destructive readout can be performed.

### [Exemplary Configuration of CMD]

The sectional view in FIG. 3 schematically shows an exemplary configuration of impurity diffusion layers formed in each CMD 200. The structure of the CMD 200 shown in FIG. 3 constitutes one pixel of the pixel area 110.

The CMD 200 shown in FIG. 3 includes a silicon semiconductor substrate 400 and a gate electrode 501A disposed on the substrate. Predetermined features such as oxide films and impurity diffusion layers of the CMD 200 are formed in appropriate positions on the semiconductor substrate 400, as will be detailed later.

A gate insulation film 401A is formed on a top surface of the semiconductor substrate 400. For example, the gate insulation film 401A may be formed using a thermal oxidation process or a CVD (chemical vapor deposition) process. The gate insulation film 401A is an example of the second gate insulation film referred to in the appended claim(s).

A channel 402 is formed in a position of the semiconductor substrate 400 under the gate insulation film 401A. A source 403 and a drain 404 are formed on both sides of the channel 402. A source electrode 403a is formed on the source 403, and a drain electrode 404a is formed on the drain 404.

A well 405a is formed in the semiconductor substrate 400 under the channel 402. A well 405b and a well 405c are formed under the source 403 and the drain 404, respectively. Further, a well 405d is formed under a sensor section 406 and the wells 405b and 405c.

The sensor section 406 is formed such that it is surrounded by the wells 405a, 405b, 405c, and 405d. The sensor section 406 is a section in which electrical charge is generated according to light incident thereon and in which the generated electrical charge is accumulated. That is, the sensor section 406 is a section performing photoelectric conversion. Each of the impurity diffusion layers of the semiconductor 400 described above can be formed by ion-implanting a predetermined substance according to an appropriate procedure.

A gate electrode 501A is formed on the gate insulation film 401A. Polysilicon (polycrystalline silicon) is used as the gate electrode 501A. The gate electrode 501A is an example of the second gate electrode as referred to in the appended claim(s).

As thus described, the CMD 200 shown in FIG. 3 has a structure which is corresponding to the equivalent circuit of a CMD shown in FIG. 2. Specifically, a section corresponding to the transistor TR shown in FIG. 2 is formed by the source 403, the channel 402, the drain 404, the gate insulation film 401A, and the gate electrode 501A. In the structure similar to the transistor TR, a current flows between the source 403 and the drain 404 through the channel 402 in parallel with the surface of the semiconductor substrate 400. The sensor section. 406 corresponds to the photodiode PD shown in FIG. 2.

### [Exemplary Structure of MOSFET]

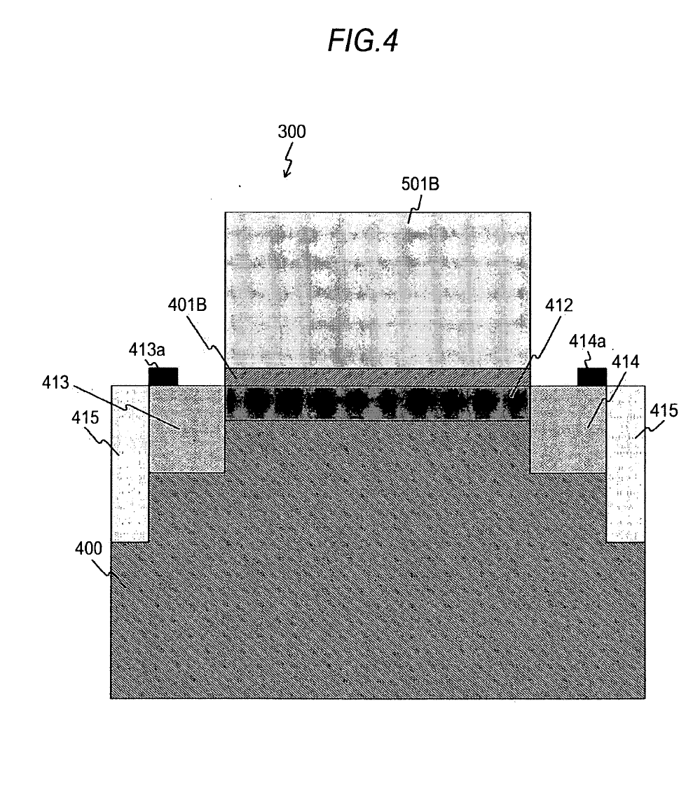

An exemplary structure of a MOSFET formed in the logic area 120 will now be described with reference to the sectional view in FIG. 4.

MOSFET 300 shown in FIG. 4 is formed by the semiconductor substrate 400 and a gate electrode 501B formed on the substrate. As described above with reference to FIG. 1, the logic area 120 and the pixel area 110 are formed on the same semiconductor substrate 400. Therefore, the semiconductor substrate 400 of the CMD 200 shown in FIG. 3 is the same semiconductor substrate 400 which is shown in FIG. 4.

A gate insulation film 401B is formed on a top surface of the semiconductor substrate 400 associated with the MOSFET 300. The gate insulation film 401B and the gate insulation film 401A of the CMD 200 shown in FIG. 3 may be formed from a layer of a common insulation film material formed on the semiconductor substrate 400 at the same manufacturing step instead of forming the films at different manufacturing steps involving a masking process. The gate insulation film 401B is an example of the first gate insulation film as referred to in the appended claim(s)

A channel 412 is formed in the semiconductor substrate 400 under the gate insulation film 401B. A source 413 and a drain 414 are formed on both sides of the channel 412. A source electrode 413a is formed on the source 413, and a drain electrode 414a is formed on the drain 414. An STI (shallow trench isolation) 415 is formed outside each of the source 413 and the drain 414.

A gate electrode 501B is provided on the gate insulation film 401B. The gate electrode 501B is formed from polysilicon like the gate electrode 501A of the CMD 200 shown in FIG. 3. The gate electrode 501B and the gate electrode 501A may be formed from a layer of a common electrode material deposited on the semiconductor substrate 400 at the same manufacturing step instead of forming the electrodes at different steps involving a masking process. The gate electrode 501B is an example of the first gate electrode as referred to in the appended claim(s).

### [Setting of Impurity Concentration of Gate Electrodes]

As shown in FIG. 3, each CMD 200 serving as a pixel includes the sensor section 406 performing photoelectric conversion, and it is preferable that a source voltage of the CMD is varied by carriers generated as a result of photoelectric conversion at the sensor section 406 with the highest possible efficiency. The channel 402 and the source electrode 403a of the CMD are modulated by carriers generated as a result of photoelectric conversion. Higher conversion efficiency can be achieved, the smaller the channel-gate capacity between the channel 402 and the gate electrode 501A relative to the sensor-channel capacity between the sensor section 406 and the channel 402. It is therefore advantageous to keep the channel-gate capacity as small as possible from the viewpoint of conversion efficiency.

On the contrary, it is preferable to provide the MOSFET 300 shown in FIG. 4 with the highest possible on/off transition characteristics by keeping the on-current of the transistor high, which results in a need for setting the channel-gate capacity of the transistor at a certain value or higher.

As thus described, contradictory requirements are placed on the channel-gate capacities of the CMD 200 and the MOSFET 300 to provide those devices with improved performance. A channel-gate capacity can be changed by changing the thickness of the gate insulation film associated therewith. The capacity of the gate insulation film can be made smaller to keep the channel-gate capacity smaller, the thicker the gate insulation film is formed.

In view the above, it may suffice if the gate insulation film 401A is formed with a large thickness in the case of the CMD 200 and the gate insulation film 401B is formed with a small thickness in the case of the MOSFET 300. In this case, the gate insulation film 401A and the gate insulation film 401B differs from each other in the thickness. Accordingly, the process of manufacturing the solid-state imaging apparatus 100 must include different steps for fabricating the gate insulation film 401A and the gate insulation film 401B separately by forming different mask patterns to be used for the films respectively. Thus, the number of manufacturing steps is increased, which results in disadvantages such as an increase in the production cost and an increase in the turn around time as described above.

The CMD 200 may be provided with higher conversion efficiency by disposing the sensor section 406 closer to the top surface of the semiconductor substrate 400 to obtain a greater sensor-channel capacity. For this purpose, the channel 402, the channel barrier, and the sensor section 406 must have a very narrow layer structure which is provided by forming a steep impurity concentration distribution in the silicon substrate. However, this approach is difficult to implement using existing techniques for ion implantation.

The present disclosure is based on the finding that the resistance of polysilicon used as a gate electrode can be set by adjusting the impurity concentration thereof. The resistance of the polysilicon can beset higher, the lower the impurity concentration thereof. However, depletion layer formed at an interface between the gate electrode and a gate insulation film is greater, the higher the resistance of the polysilicon. A depletion layer formed as thus described has a capacity. Hereinafter, the capacity of such a depletion layer may be referred to as “depletion layer capacity”. Since the depletion layer capacity is added in series with the gate insulation film, the capacity is in, series with the capacity of the gate insulation film. In this case, a channel-gate capacity is formed as a result of series connection of the gate insulation film capacity and the depletion layer capacity. Therefore, the channel-gate capacity is smaller, the greater the depletion layer capacity. Thus, the channel-gate capacity can be adjusted by setting the impurity concentration of the gate electrode at a low value such that the capacity will be equal to a value obtained by setting the thickness of the gate insulation film at a great value.

In the embodiment of the present embodiment disclosure, the gate electrode 501A of the CMD 200 shown in FIG. 3 is provided with an impurity concentration lower than that of the gate electrode 501B of the MOSFET 300 shown in FIG. 4. In order to obtain high on/off transition characteristics, the impurity concentration of the gate electrode 501B of the MOSFET 300 shown in FIG. 4 is preferably set such that the channel-gate capacity will be kept at a predetermined value or higher.

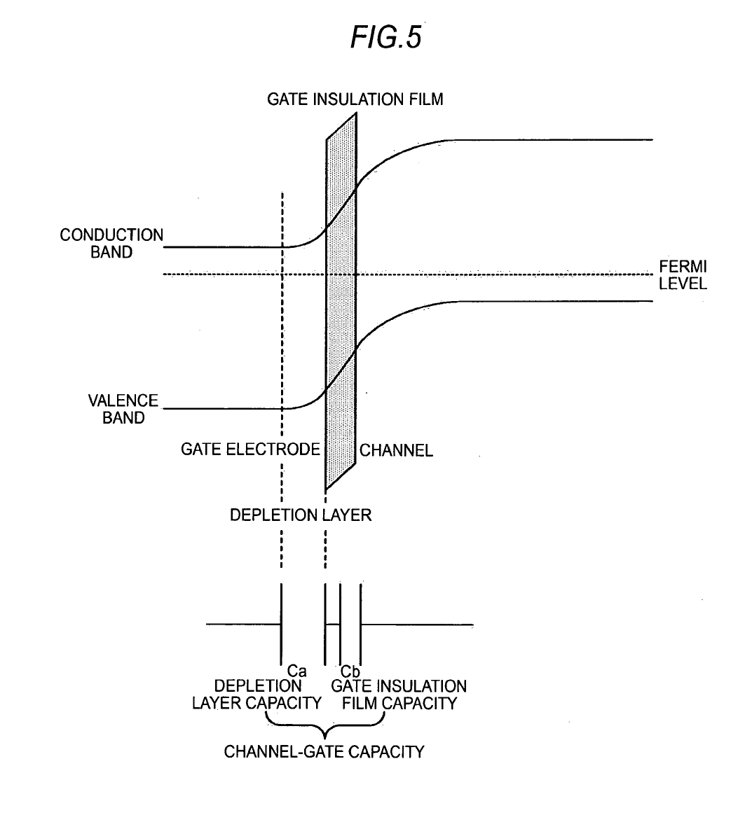

FIG. 5 is a band diagram showing the state of the interface between the gate electrode 501A and the gate insulation film 401A of the CMD 200. When the impurity concentration of the gate electrode 501A is set at a low as thus described, a depletion layer is formed at the interface between the gate electrode 501A and the gate insulation film 401A as described above, and a depletion layer capacity Ca is generated. As a result, as shown in FIG. 5, the channel-gate capacity is formed by the depletion layer capacity Ca and a gate insulation film capacity Cb which are series-connected. Therefore, the channel-gate capacity is smaller, the smaller the depletion layer capacity Ca. Higher conversion efficiency can be achieved by keeping the channel-gate capacity of the CMD 200 small as thus described.

On the contrary, the gate electrode 501B of the MOSFET 300 shown in FIG. 4 is formed such that it will have a predetermined impurity concentration higher than that of the gate electrode 501A of the CMD 200 as described above.

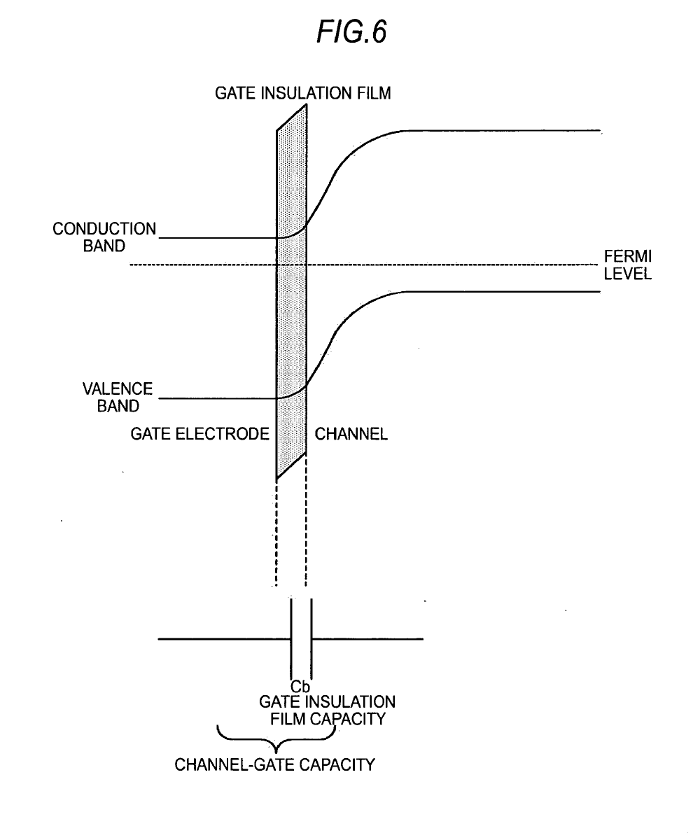

FIG. 6 is a band diagram showing the state of the interface between the gate electrode 501B and the gate insulation film 401B of the MOSFET 300. Since the impurity concentration of the gate electrode 501B is set at a predetermined value or higher, the generation of a depletion layer at the interface between the gate electrode 501B and the gate insulation film 401B is suppressed. In this state, a depletion layer capacity generated at the interface will be suppressed at predetermined value or less. For better understanding of the difference from the state shown in FIG. 5, FIG. 6 shows a case in which no depletion layer capacity Ca is generated by way of example. The channel-gate capacity of the MOSFET 300 is set greater than that of the CMD 200 because the depletion layer capacity connected in series with the gate insulation film capacity Cb is small as thus described. The MOSFET 300 can be provided with high on/off transition characteristics by setting the channel-gate capacity such that an on-current of a predetermined value or more can be passed through the device.

Let us assume that the gate electrode 501B of the MOSFET 300 which may be of N-type has an impurity concentration set at 1.0×10²⁰/cm³. Let us also assume that the gate electrode 501A of the CMD 200 which may also be of N-type has a lower impurity concentration, e.g. 1.0×10¹⁷/cm³. In this case, the channel-gate capacity of the CMD 200 is as small as one-half of the channel-gate capacity of the MOSFET 300, and the gate insulation film 401A has an effective thickness which is twice the effective thickness of the gate insulation film 401B. The conversion efficiency of the CMD 200 is about 25% higher than the efficiency achieved by setting the impurity concentration of the gate electrode 501A at the same value as the impurity concentration of the gate electrode 501B of the MOSFET 300.

Another possible method of setting the resistance of the gate electrode 501A of the CMD 200 at a high value is to use a transparent electrode made of a material having high resistance such as ITO (indium tin oxide) or SiO₂ as the gate electrode 501A. However, since a transparent electrode made of the same high resistance material cannot be used as the gate electrode 5015 of the MOSFET 300, a material other than such a transparent electrode must be used as the gate electrode 501B. The layers of electrode materials associated with the gate electrodes 501A and 501B must be formed using different processes. In comparison to a structure formed as thus described, the present embodiment of the present disclosure is advantageous in terms of the number of manufacturing steps required.

### [Exemplary Steps of Manufacturing Solid-State Imaging Apparatus]

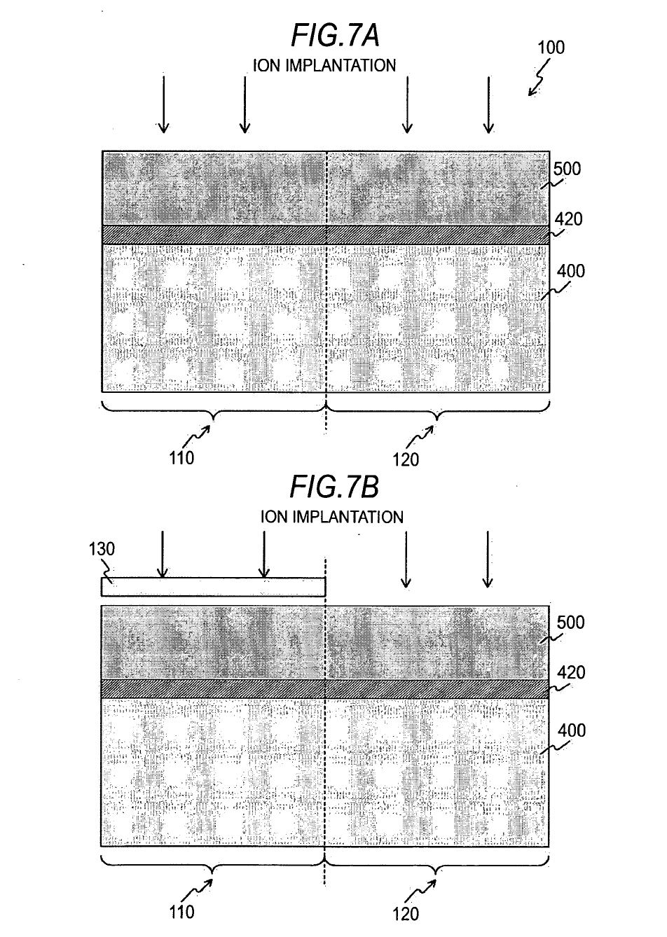

Exemplary steps of manufacturing a solid-state imaging apparatus 100 according to the present embodiment will now he described. FIG. 7A is a view of the solid-state imaging apparatus 100 taken at a phase of manufacture at which an electrode material layer 500 has been formed on a top surface of a semiconductor substrate 400. As illustrated, the electrode material layer 500 is commonly formed in a pixel area 110 and a logic area 120. An insulation material layer 420 is also formed in the pixel area 110 and the logic area 120 commonly. The insulation material layer 420 is a layer which will be processed into gate insulation films 401A of CMDs 200 and gate insulation films 401B of MOSFETs 300, as shown in FIGS. 3 and 4. Various features constituted by impurity diffusion layers formed in the semiconductor substrate 400 are omitted in the figure.

In the state shown in FIG. 7A, a first step of ion implantation is carried out to set the resistance of the electrode material layer 500. As will be understood from the above description, gate electrodes 501A of the CMDs 200 are to be set at a lower impurity concentration. Therefore, the first step of ion implantation is carried out using a dose set to obtain an impurity concentration at which the gate electrodes 501A are to be set. Thus, an impurity concentration set for the gate electrodes 501A is imparted to the electrode material layer 500 throughout the pixel area 110 and the logic area 120.

Next, a mask 130 is provided on the electrode material layer 500 as shown in FIG. 7B. The mask 130 is formed using a mask pattern which is designed such that the pixel area 110 will be masked and such that the logic area 120 will not be masked.

Thereafter, a second step of ion implantation is carried out for setting the resistance of the electrode material layer 500 as shown in FIG. 7B. The substance ion-implanted at the second step is the same substance implanted at the first step.

At this stage, the impurity concentration set for the gate electrodes 501A has already been imparted to the electrode material layer 500. Therefore, the second step of ion implantation is carried out using a dose set according to a difference between an impurity concentration to be set for the gate electrodes 501B and the impurity concentration to be set for the gate electrodes 501A. In this case, since the pixel area 110 is masked by the mask 130, the impurity concentration of the area does not increase as a result of the second step of ion implantation, and the area can be kept at the impurity concentration set for the gate electrodes 501A. On the contrary, the impurity concentration of the logic area 120 which is not masked increases as a result of the second step of ion implantation, and the impurity concentration set for the gate electrodes 501B is consequently imparted to this area.

As thus described, two steps of ion implantation including a masking process are carried out on the electrode material layer 500 in the present embodiment of the present disclosure. As a result, different impurity concentrations can be imparted to one electrode material layer 500. That is, the impurity concentration set for the gate electrodes 501A of the CMDs 200 can be imparted to the pixel area 110, and the impurity concentration set for the gate electrodes 501B of the MOSFETs 300 can be imparted to the logic area 120.

The above-described steps allow the electrode material layer 500 of the present embodiment of the present disclosure to be formed to cover the pixel area 110 and the logic area 120 commonly. Further, since there is no need for forming the gate insulation films 401A of the CMDs 200 and the gate insulation films 401B of the MOSFETs 300 with different thicknesses, the insulation film material layer 420 can be also formed to cover the pixel area 110 and the logic area 120 commonly. Thus, it is not required to form the electrode material layer 500 and the insulation film material layer 420 differently in the pixel area 110 and the logic area 120, and the number of manufacturing steps can therefore be kept small.

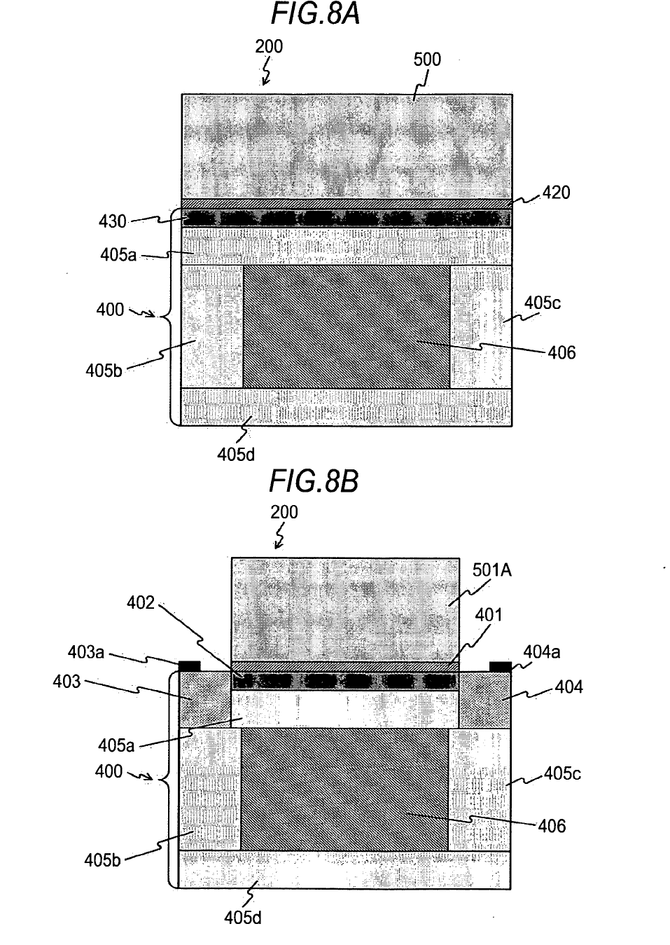

FIG. 8A is a view of a part of the pixel area 110 including one CMD 200 therein taken after the manufacturing step described above with reference to FIG. 7B. At this stage, the electrode material layer 500 and the insulation film material layer 420 remain in place as illustrated. The semiconductor substrate 400 has wells 405a, 405b, 405c, and 405d, a sensor section 906, and a layer 430 to become a channel formed therein, and neither source 403 nor drain 404 has been formed yet.

In this state, for example, a photolithographic process is performed on the electrode material layer 500 to form the gate electrode 501A and the gate electrode insulation film 401A as shown in FIG. 8B. Thereafter, ion implantation is carried out using a technique which disallows ions to pass through the gate electrode, whereby impurity diffusion layers to serve as the source 403 and the drain 404 are formed so as to replace parts of the layer 430 and the well 405a which are not located under the gate electrode 501A. As a result, the part of the layer 430 remaining between the source 403 and the drain 404 constitutes the channel 402. The source electrode 403a and a drain electrode 404a are formed on the source 403 and the drain 404, respectively. Thus, the CMD 200 is formed.

In the logic area 120 formed through the steps shown in FIGS. 7A and 7B, the gate electrodes 501B of the MOSFETs 300 can be formed simultaneously with formation of the gate electrodes 501A at the same manufacturing step described with reference to FIG. 8A. Alternatively, the gate electrodes 501B may be formed simultaneously with the formation of the source 403 and the drain 404 at the same step described with reference to FIG. 8B if those features can be formed by implanting the same substance in the same dose.

The gate electrodes 501A of the CMDs 200 formed as thus described have such a low impurity concentration that depletion layers can be generated as described above. On the contrary, the gate electrodes 501B of the MOSFETs 300 have such a high impurity concentration that required on/off transition characteristics can be achieved.

### 2. Modifications

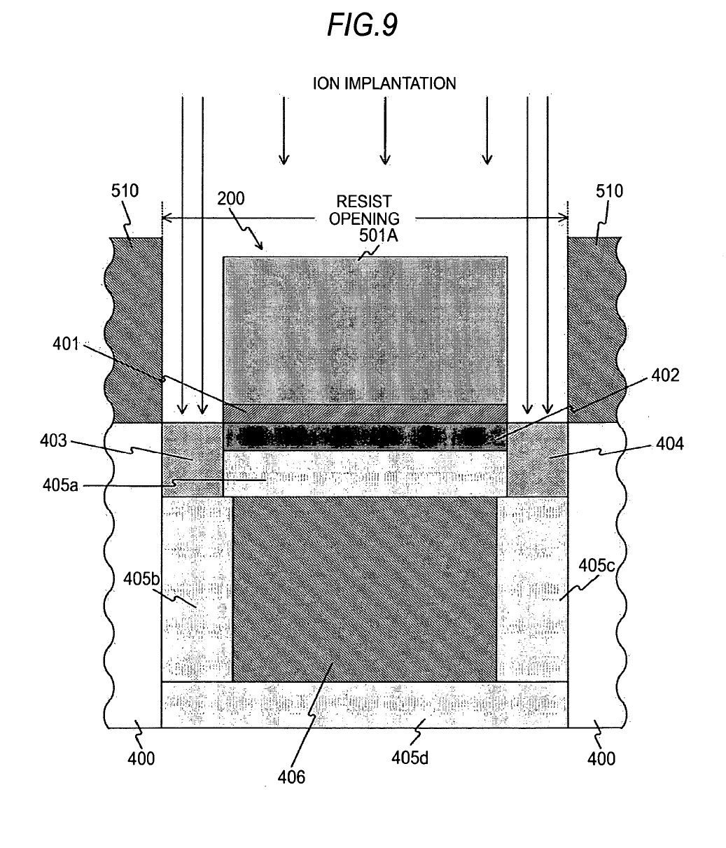

Modifications of the embodiment of the present disclosure will now be described. In the procedure described above with reference to FIGS. 7A, 7B, 8A, and 8B, the ion implantation for setting the resistance of the gate electrodes is carried out before the electrode material layer 500 is processed into the gate electrodes. Alternatively, the ion implantation for setting the resistance of the gate electrodes may be carried out as shown in FIG. 9.

FIG. 9 is a view of the CMD 200 taken at a stage where the gate electrode 501A has already been formed. In this case, the ion implantation for setting the resistance of the gate electrode is not carried out before processing the electrode material layer 500 into the gate electrode. Instead, an impurity concentration is imparted to the gate electrode 501A simultaneously with the formation of the source 403 and the drain 404 when ion implantation is carried out to form those features. At this time, a resist layer 510 formed to implant ions in regions to be processed into the source 403 and the drain 404 may be formed with a resist opening such that the regions of the source 403, the drain 404, and the gate electrode 501A will not be masked. The impurity concentration of the gate electrodes 501B of the MOSFETs 300 must be set at a value higher than the impurity concentration of the gate electrodes 501A of the CMDs 200. For this purpose, the following steps may be taken. At the above-described manufacturing step for forming the sources 403 and the drains 404, ions may be simultaneously implanted in regions to become the gate electrodes 501B to impart the impurity concentration set for the gate electrodes 501A to the regions. At an ion-implanting step for forming predetermined impurity diffusion layers preceding or following the above-described step, the regions of the gate electrodes 501B may be also ion-implanted with the regions of the gate electrodes 501A masked.

The following steps may alternatively be taken. When the electrode material layer 500 is deposited and formed, ion implantation may be simultaneously carried out to impart an impurity concentration to the electrode material layer 500. Doping carried out simultaneously with the formation of a layer may be referred to as “in-situ doping”. The dose of the in-situ doping is set such that the impurity concentration set for the gate electrodes 501A of the CMDs 200 will be imparted to the electrode material layer. Thereafter, ion implantation is carried out with the pixel area 110 masked, for example, as shown in FIG. 7B to impart the impurity concentration set for the gate electrodes 501B to the electrode material layer 500 in the logic area 120.

As an alternative to the step shown in FIGS. 7A and 7B, the following steps may be taken. One area of the pixel area 110 and the logic area 120 may be first masked, and ion implantation may be carried out to impart the impurity concentration associated with the gate electrodes to be formed in the other area which is not masked. Then, the other area is masked and ion implantation is carried out to impart the impurity concentration associated with the gate electrodes to be formed in the one area. In this case, however, there is a need for two manufacturing steps for forming different mask patterns to be used for doping the areas with the same impurity. Therefore, the step described above with reference to FIGS. 7a and 7B is more advantageous in reducing the number of manufacturing steps.

In the above-described embodiment of the present disclosure, two different impurity concentrations are set for gate electrodes associated with two areas, i.e., the pixel area 110 including the CMDs 200 and the logic area 120 including the MOSFETs. For example, the present embodiment of the present disclosure can be applied when three or more areas having different functions are formed on the semiconductor substrate 400 and gate electrodes provided in the regions respectively are to be set at different impurity concentrations.

The embodiment of the present disclosure is an example of the implementation of the present disclosure. As stated above with reference to the embodiments of the present disclosure, there is correspondence between features of the embodiment of the present disclosure and features referred to in the appended claim(s). Also, there is correspondence between the elements referred to in the appended claim(s) and the elements in the embodiments of the present disclosure with the same or similar names. The present disclosure is not limited to the above-described embodiment, and the present disclosure may be implemented in various modified forms without departing from the spirit of the present disclosure.

The present disclosure contains subject matter related to that disclosed in Japanese Priority Patent Application JP 2010-240386 filed in the Japan Patent Office on Oct. 27, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

The present application is a division of U.S. patent application Ser. No. 13/200,645 filed on Sep. 28, 2011 which claims priority of Japanese Patent Application No. JP2010-240386 filed in the Japan Patent Office on Oct. 27, 2010, the entire contents of which are incorporated herein by reference.

1. A semiconductor apparatus comprising:
a first channel region of a semiconductor substrate between a source region of a first transistor and a drain region of the first transistor, said first channel region touching said source region of the first transistor and said drain region of the first transistor;
a second channel region or a semiconductor substrate between a source region of a second transistor and a drain region of the second transistor, said second channel region touching said source region of the second transistor and said drain region of the second transistor;
a first insulation film between a first gate electrode of a conductivity type and said first channel region, said first insulation film touching said first gate electrode and said first channel region, wherein the first gate electrode is made of a first transparent material;
a second insulation film between a second gate electrode of a conductivity type and said second channel region, said second insulation film touching said
second gate electrode and said second channel region,
wherein the second gate electrode is made of a second transparent material different from the first transparent material,
wherein a thickness of the first insulation film is less than a thickness of the second insulation film, an impurity concentration of the conductivity type in said second gate electrode being lower than an impurity concentration of the conductivity type in said first gate electrode.

2. A semiconductor apparatus according to claim 1, wherein only an impurity of the conductivity type is within said second gate electrode.

3. A semiconductor apparatus according to claim 1, wherein said conductivity type is N-type.

4. A semiconductor apparatus according to claim 1, further comprising:
a first portion of a well region between said second channel region and a sensor section of the semiconductor substrate, said sensor section being between a second portion of the well region and said first portion.

5. A semiconductor apparatus according to claim 4, wherein said sensor section is configured to convert light into an electrical charge.

6. A semiconductor apparatus according to claim 4, wherein cathode of the sensor section is at a boundary between said sensor section and said first portion, an anode of the sensor section is at a boundary between said sensor section and said second portion.

7. A semiconductor apparatus according to claim 4, wherein said second portion is directly electrically connected to ground.

8. A semiconductor apparatus according to claim 4, wherein said first portion touches said second channel region and said sensor section, said source region of the second transistor and said drain region of the second transistor touching said first portion.

9. A semiconductor apparatus according to claim 4, further comprising:
a third portion of the well region between said source region of the second transistor and said second portion, a fourth portion of the well region being between said drain region of the second transistor and said second portion.

10. A semiconductor apparatus according to claim 9, wherein said third portion touches said source region of the second transistor and said second portion, said fourth portion touching said drain region and said second portion.

11. A semiconductor apparatus according to claim 9, wherein said sensor section touches third portion and said fourth portion.

12. A semiconductor apparatus according to claim 1, wherein said first gate electrode and said second gate electrode are doped with a substance of the conductivity type.

13. A semiconductor apparatus according to claim 12, wherein said source region of the second transistor and said drain region of the second transistor are doped with said substance.

14. A semiconductor apparatus according to claim 1, wherein said source region of the second transistor is of said conductivity type.

15. A semiconductor apparatus according to claim 14, wherein said drain region of the second transistor is of said conductivity type.

16. A semiconductor apparatus according to claim 1, wherein said first channel region is in a circuit area of the semiconductor substrate, said second channel region being in a pixel area of the semiconductor substrate.

17. A semiconductor apparatus according to claim 1, wherein said first insulation film and said second insulation film are of a same insulation film material layer.

18. A semiconductor apparatus according to claim 1, wherein said first insulation film is an oxide, and said second insulation film being said oxide.
